(19) United States
(12) Patent Application Publication
(10) Pub. No.: US 2010/0181925 A1
(43) Pub. Date: Jul. 22, 2010

(54) Ballast/Line Detection Circuit for Fluorescent Replacement Lamps

(75) Inventors: John Ivey, Farmington Hills, MI (US); Francis Palazzolo, Rochester, MI (US)

Correspondence Address: YOUNG BASILE, 3001 WEST BIG BEAVER ROAD, SUITE 624, TROY, MI, 48084, US

(73) Assignee: ALTAIR ENGINEERING, INC., Troy, MI (US)

(21) Appl. No.: 12/689,340

(22) Filed: Jan. 19, 2010

Related U.S. Application Data
(60) Provisional application No. 61/146,164, filed on Jan. 21, 2009.

(51) Int. Cl. H05B 41/36; G01R 31/00

(52) U.S. Cl. 315/224; 315/291; 324/403

(57) ABSTRACT

Disclosed herein is a replacement light for a fluorescent tube usable in a fluorescent fixture connected to a power source and containing at least one LED, the improvement including a detection circuit for connection to the power source, the detection circuit configured to identify the power source.

### CROSS-REFERENCE TO RELATED APPLICATIONS

This application claims priority to U.S. Provisional Patent Application Ser. No. 61/146,164, filed Jan. 21, 2009, which is hereby incorporated by reference in its entirety.

### FIELD OF THE INVENTION

The present invention relates to a ballast/line detection circuit for fluorescent replacement lamps.

### BACKGROUND

LED light sources are rapidly becoming competitive with fluorescent lamps with respect to luminous efficacy. Known LED light sources typically require rewiring the fixture so that line voltage is directly connected to the LED lamp connectors, bypassing the ballast. LED light sources have been developed that connect the replacement LED lamp to the output of the ballast. Accordingly, it has become more difficult to replace existing fluorescent lamps, since it may not be readily apparent if a fixture has been rewired to bypass the ballast, or is still wired through the ballast without at least partial disassembly of the light fixture.

### SUMMARY

It is desirable to be able to replace existing fluorescent lamps with LED sources without replacing the fixture that contains the lamps, due to the cost, time, and disruption caused by replacing a fixture as opposed to replacing a lamp. When replacing fluorescent lamps in this way, it is possible to either connect the replacement lamp to the output of the ballast, or to rewire the fixture so that line voltage is directly connected to the lamp connectors, bypassing the ballast. Each of these configurations has advantages and disadvantages. The ballast connection, for example, permits lamp replacement by untrained personnel, has a very quick relamp time, permits mixing of LED and fluorescent lamps in the same fixture, and permits easy relamping back to fluorescent. The ballast-free (direct to AC line) connection, for example, permits the elimination of the ballast and its noise, lifetime limit, and heat production. It also can eliminate the power that is necessarily wasted in the ballast. Since both configurations have advantages in different situations, it is desirable for non-fluorescent replacement lamps to be usable without change with or without a fluorescent ballast.

Other applications of the present invention will become apparent to those skilled in the art when the following description of the best mode contemplated for practicing the invention is read in conjunction with the accompanying drawings.

### BRIEF DESCRIPTION OF THE DRAWINGS

The description herein makes reference to the accompanying drawings wherein like reference numerals refer to like parts throughout the several views, and wherein:

FIG. 1 is an exemplary ballast/line detection circuit diagram for fluorescent replacement lamps;

FIG. 2 is a plot of lamp voltage and impedance characteristics with respect to current of a cold cathode fluorescent lamp as known in the art;

FIG. 3 is a simplified schematic diagram of the detection circuit associated with an AC line power source and a fluorescent replacement lamp;

FIG. 4 is a simplified schematic diagram of the detection circuit associated with a ballast power source and a fluorescent replacement lamp; and

FIG. 5 is an exemplary block diagram of a control circuit used in the ballast/line detection circuit diagram of FIG. 1.

### DETAILED DESCRIPTION

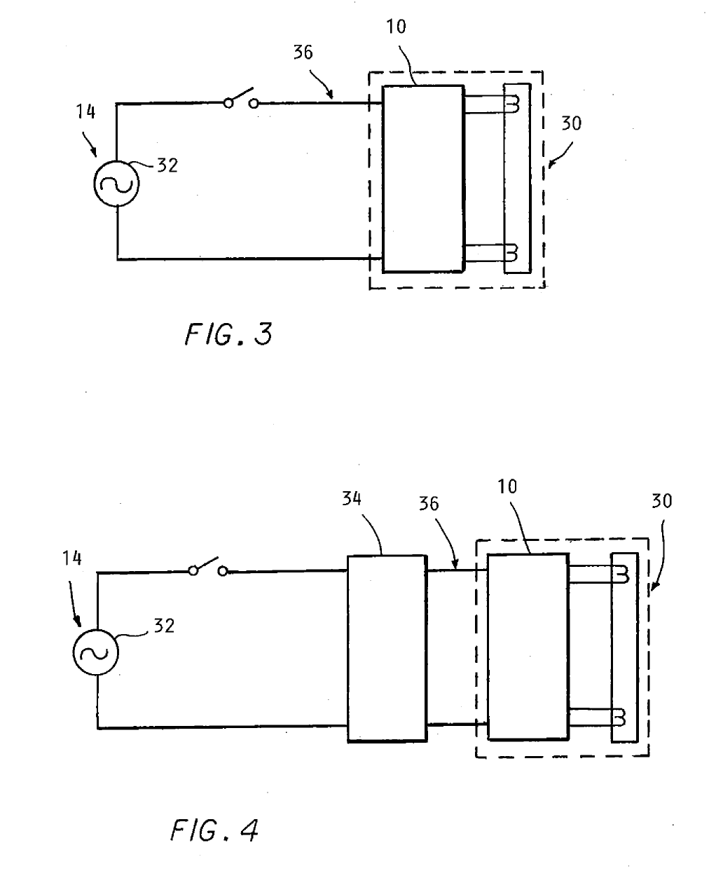

Referring to FIGS. 3 and 4, there are differences in the control scheme required when using a ballast 34 output as a power source (FIG. 4) instead of solely using an AC line 32 output as the power source (FIG. 3). As illustrated in FIG. 4, ballast 34 can convert the power from AC line 32 to a power level designed to activate and operate a fluorescent lamp. For example, ballast 34 outputs a resistive load line, with for example, a very high equivalent voltage and a relatively high resistance. Typical values for a ballast can be approximately 600V and approximately 2500 k ohm impedance. Ballast 34 can be any type of ballast suitable for lighting fluorescent lamps. Some non-limiting examples of ballast 34 are rapid start electronic ballasts, instant start electronic ballasts, magnetic ballasts or a hybrid containing components of both the electric and magnetic ballasts. Further, although the following description refers to the presence of AC line 32, any power source may be used in lieu of AC line 32, including a DC source.

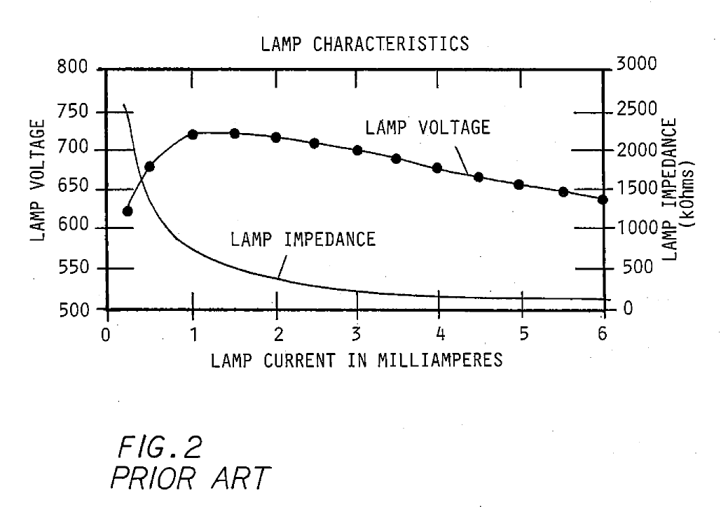

As one non-limiting example, the normal operating point of replacement lamp 30 can be around 120V and 220 mA. Of course, other replacement lamps can operate at different operating points. When replacement lamp 30 is operating from ballast 34, the power in lamp 30 increases as the current in lamp 30 decreases, and vice versa, because the operating point voltage of lamp 30 is below the maximum power point of the ballast. This is because a small decrease in current can result in a relatively large increase in voltage, as illustrated in FIG. 2 and as known in the prior art.

On the other hand, when replacement lamp 30 is operating from the AC line source 32, the power in lamp 30 increases as the lamp current increases, and vice versa, because the voltage does not change with current. As a result of the fundamental incompatibility of the two types of power sources, any control scheme that attempts to operate with both of these power sources must be able to handle the differences between a ballast source and an AC line source.

Accordingly, it is important to correctly detect which power source 14 is present. While the embodiments described herein refer to identifying the power source as an AC line or ballast, reference to the ballast 34 does not necessarily mean the absence of an AC line connection but yet refers to a power source that may contain both the AC line and the ballast. If a control scheme suitable for AC line 32 source is used with the ballast 34, the input voltage can increase to the maximum available from ballast 34. It may be impractical to provide components that can withstand the maximum voltage ballast 34 can deliver (e.g., up to 1200V) when the normal operating point of the replacement lamp 30 is, for example, around 1/10 of that value. Conversely, if a control scheme suitable for ballast 34 is employed when connected to the AC line 32, the current into the lamp 30 may increase without limit, until component failure or another limit intervenes.

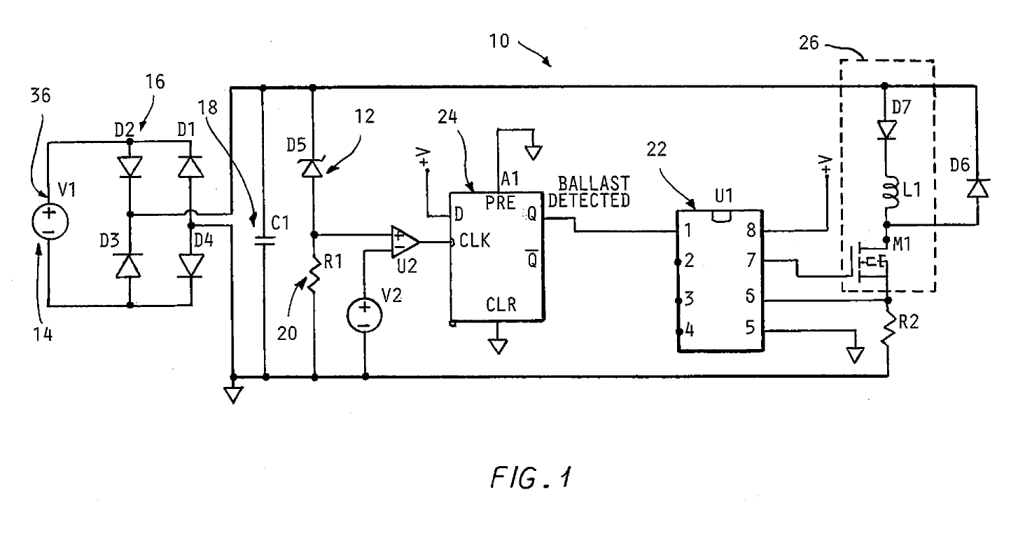

Referring now to FIG. 1, an exemplary ballast/line detection circuit 10 for a replacement lamp 30 is illustrated. In one embodiment of the present invention, circuit 10 can limit both the maximum voltage and can also detect which type of power source 14 is being used. Power source 14 can provide, for example, an input signal 36 to full-wave rectifier 16, which receives the input signal 36 and outputs a rectified voltage using diodes D1-D4. Other suitable rectifier devices and techniques for determining suitable rectifier devices are also available.

The rectified voltage is smoothed by a filter 18, which is connected across rectifier 16. Filter 18 can be realized by capacitor C1. Alternatively, filter 18 can be realized by any other suitable number of capacitors. A shunt regulator 12 and a current-limiting resistor 20 are placed in parallel with filter 18. Shunt regulator 12, as illustrated in FIG. 1, includes a Zener diode D5. However, embodiments of the present invention are not limited to using a Zener diode and other suitable devices for regulating and/or shunting voltage are available. Zener diode D5 can be utilized to detect a high-voltage condition from the rectified voltage and further can prevent excessive voltages from power source 14 from damaging other components. Accordingly, for example, Zener diode D5 can be selected such that it has a Zener voltage at least higher than the maximum voltage of AC input line 32. In turn, the Zener diode will not conduct when AC input line 32 voltage is connected to the input 36, but will conduct when ballast 34 is connected. The voltage of Zener diode D5 can also be set low enough such that any voltage-sensitive components (rectifiers, filter capacitors, FETs, etc.) are not damaged. Zener diode D5 and current-limiting resistor 20 are connected such that they provide a relatively constant voltage at a point therebetween.

To identify the type of power source 14, the circuit 10 detects when Zener diode D5 is conducting by detecting the current flowing therein. Input signal 36 can be latched because the normal operating point of the lamp 30 can be very similar for both AC line 32 and ballast 34 operation. It is the incremental change that is different. However, in other embodiments, input signal 36 will not be latched.

The Zener diode D5 can be chosen so that it does not conduct when the power source 14 is AC line 32 without ballast 34. For example, if the line voltage is 120 VAC, the Zener breakdown voltage can be set higher than a peak line voltage (e.g. 168V). Accordingly, for example, the Zener breakdown voltage can be 200 V. Since the Zener diode is set up to not conduct, the voltage across a resistor 20 will be below that of a reference voltage V2. Accordingly, an inverting input (V−) of a voltage comparator U2 will be at a greater voltage than a non-inverting input (V+). In turn, the output of comparator U2, which is connected to a clock input (CLK) of an integrated circuit 24, outputs a value (e.g., negative or zero voltage) that will not set clock input (CLK). Integrated circuit 24, as illustrated in FIG. 1, is a D flip-flop A1. However, in other embodiments, other integrated circuits such as toggle flip-flops, set-reset flip-flops, etc. or any other suitable combination of electrical componentry may be used in lieu of or in combination with D flip-flop A1. The detection of power source 14 can also be implemented using any other combination of hardware and/or software. For example, the detection scheme can also be implemented in a programmed microcontroller using analog to digital converters or other voltage sensing technology.

As is well known in the art, if clock input (CLK) is not set, non-inverted output (Q) of D flip-flop A1 will output a signal representing that ballast 34 has not been detected. In other words, for example, the non-inverted output (Q) will be set to a logical 0 and in turn, control circuitry 22 can be configured to operate as if AC line 32 is the power source 14 without ballast 34.

On the other hand, when the power source 14 includes the ballast 34, the rectified voltage will rise until the Zener diode D5 conducts. When the Zener diode D5 current is sufficiently high that the voltage across resistor 20 is above reference voltage V2, non-inverting input (V+) of voltage comparator U2 will be at a greater voltage than inverting input (V−). In turn, the output of the comparator U2, outputs a value (e.g., positive voltage) that will set clock input (CLK). Accordingly, when clock input (CLK) is set, non-inverted output (Q) will output a signal representing that ballast 34 has been detected. For example, non-inverted output (Q) will be set to a logical 1 and in turn, control circuitry 22 can be configured to operate as if the ballast 34 is included in the power source 14.

Once power source 14 is identified, the correct control algorithm or circuit can be engaged. The control circuit 22 can then set and maintain the correct operating point of the lamp 30 to avoid damage to components. For example, if power source 14 does not include ballast 34, control circuit 22 will operate in a manner in which increasing current drawn from the power source 14 increases the power drawn from the AC line 32, and vice versa. Further, for example, if ballast 34 is detected, as discussed above, control circuit 22 will operate in a manner in which increasing current drawn from the power source 14 decreases the power drawn from the ballast 34, and vice versa.

Control circuit 22 can be any suitable controller device that can provide current regulation to LED D6 through power converter 26. The manner in which the current is regulated, as discussed previously, can depend on whether ballast 34 is part of power source 14. Further, although controller circuit 22 is shown as including IC U1, other suitable control circuits are available that may not utilize an integrated circuit or have a different configuration.

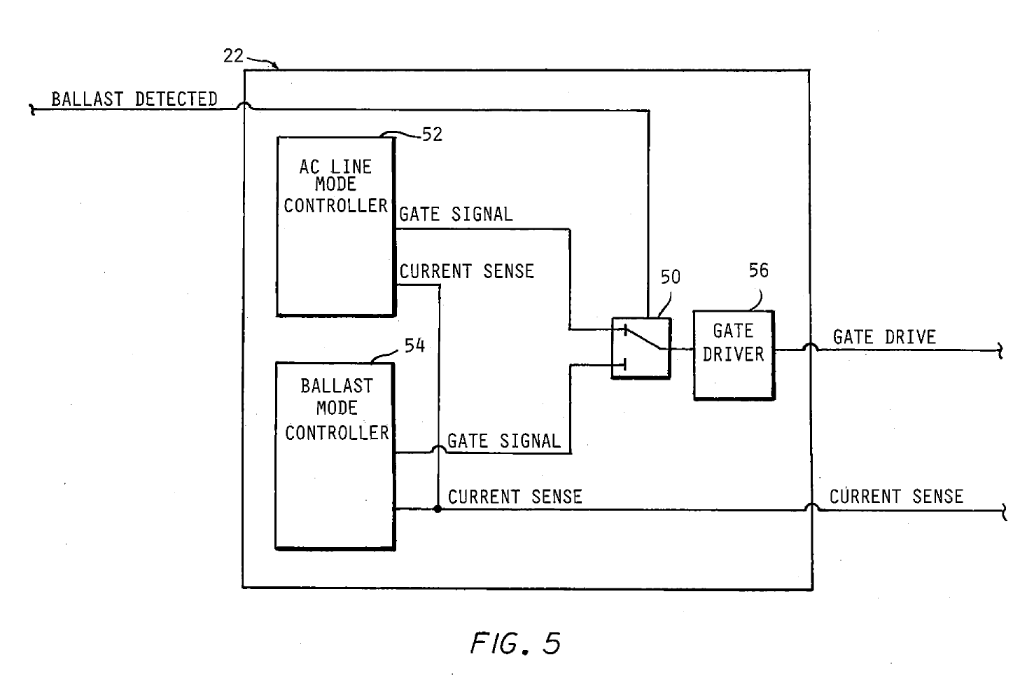

FIG. 5 illustrates an exemplary block diagram of a control circuit 22. The control circuit 22 includes a multiplexer 50 for switching between an AC line mode controller 52 and a ballast mode controller 54 in response signal outputted from integrated circuit 24 representing that ballast 34 has been detected (or not detected). Thus, for example, the ballast detected signal can function as a control signal to the multiplexer 50.

The control scheme used when the AC line mode controller 52 is selected can be any suitable control scheme for providing power to LED D6 from AC line 14. For example, the control scheme can include peak current control, average current mode control, PWM duty cycle control and/or any other suitable control scheme. The AC line mode controller 52 may optionally receive current, power, or light output feedback from LED D6. As illustrated and as will be discussed in more detail below, AC line mode controller 52 receives current feedback from LED D6. When the multiplexer has detected that ballast 34 has not been detected, the AC line mode controller 52 provides a gate signal through the multiplexer and through a gate driver 56. The gate driver 56 provides a gate driver signal to a power converter 26, as will be discussed in more detail below.

The control scheme used when the ballast mode controller 54 is selected can be any suitable control scheme for providing power to LED D6 from ballast 34. For example, the control scheme can include providing a control scheme where the AC Line mode controller 52 provides a constant gate signal (i.e. turning on switch M1 at 100% duty cycle) so that the current through LED D6 may be regulated by the ballast 34. Alternatively, any other control scheme may be used through. Again, similar to that AC line mode discussed above, the ballast mode controller 54 may optionally receive current, power, or light output feedback from LED D6. As illustrated and as will be discussed in more detail below, ballast mode controller 54 receives the same current feedback as AC line mode controller 52. Other suitable control scheme schemes are also available that may be used in lieu of or in addition to the ballast mode control scheme discussed above. For example, one such control scheme includes PWM duty cycle control with reverse feedback gain. The reverse feedback can provide the average current across LED(s) and invert a signal representing the average current so that, at any given operating point, increasing a current drawn from the source will increase LED power and decreasing the current drawn from the source will decrease LED power. Another such control scheme includes the addition of a shunt regular to limit the voltage from the ballast 34. Of course, other control schemes are available.

Power converter 26 is shown in FIG. 1 as including diode D7, inductor L1 and switch M1, although other power converters including different or additional components are available. The switch M1 can operate in response to, for example, a pulse width modulated (PWM) ON/OFF control signal from IC U1. A current sense resistor R2 electrically coupled to the switch M1 and IC U1 can sense the current running through LED D6 in order to provide current feedback to IC U1. Of course, other control circuits such as other integrated circuits, a combination of electrical componentry or a fixed oscillator can be used. Further, power converter 26 can also be realized by any other configuration (e.g., step-up, step-down, flyback, buck-boost, etc.). Additionally, in other embodiments, the power converter 26 may be a power-factor correcting converter

If ballast 34 is included in the power source 14 and is wrongly identified as an AC line 32 source due to, for example, low voltage of input signal 36, detection circuit 10 can switch to the “ballast detected” mode of operation when the voltage eventually rises. As discussed previously, once the voltage rises to the Zener voltage, the Zener diode D5 will conduct, and the ballast 34 can correspondingly be detected. If the Zener diode D5 energy and power capacity is sufficiently high, the protective action of the Zener diode D5 can permit a delayed start of the control circuitry 22 without damaging other electrical components.

The detection circuit 10 can be associated with or built into the fluorescent replacement lamp 30, as shown in phantom line in FIGS. 3 and 4, allowing installation of a fluorescent replacement lamp 30 without necessitating the installer to check whether the power source 14 includes ballast 34 or AC line 32. Although only one LED is shown in detection circuit 10, multiple LEDs can be used. The LEDs can be surface-mount devices of a type available from Nichia, though other types of LEDs can alternatively be used. Further, other light sources, such as incandescent lights or fluorescent lights, may be used in combination with LED of detection circuit 10.

While the invention has been described in connection with what is presently considered to be the most practical and preferred embodiment, it is to be understood that the invention is not to be limited to the disclosed embodiments but, on the contrary, is intended to cover various modifications and equivalent arrangements included within the spirit and scope of the appended claims, which scope is to be accorded the broadest interpretation so as to encompass all such modifications and equivalent structures as is permitted under the law.

What is claimed is:

1. In a replacement light for a fluorescent tube usable in a fluorescent fixture connected to a power source and containing at least one LED, the improvement comprising:
a detection circuit for connection to the power source, the detection circuit configured to identify the power source.

2. The improvement of claim 1, wherein the power source includes one of an AC line with a ballast and an AC line without the ballast.

3. The improvement of claim 1, wherein the detection circuit is configured to detect a high-voltage condition based on a voltage from the power source.

4. The improvement of claim 1, wherein the detection circuit is further configured to limit a maximum voltage applied to the replacement light.

5. The improvement of claim 1, wherein the detection circuit further comprises:
a Zener diode having a Zener voltage setting sufficiently high to not conduct when a voltage input from an AC line is connected to the detection circuit, and sufficiently low to conduct when a voltage input from the ballast is connected to the detection circuit.

6. The improvement of claim 5, wherein the detection circuit is configured to detect Zener conduction by detecting a current flowing through the Zener diode.

7. The improvement of claim 1, wherein the detection circuit comprises:
a full-wave rectifier electrically coupled to the power source and configured to produce a rectified voltage output;
a smoothing filter electrically coupled to the full wave rectifier and configured to produce a smoothed rectified voltage output;
a Zener diode and a resistor electrically coupled in parallel to the smoothing filter; and
a comparator, wherein one input of the comparator is electrically coupled to a point between the Zener diode the resistor and another input of the comparator is electrically coupled to a reference voltage.

8. The improvement of claim 7, wherein the detection circuit further comprises:
a D flip-flop configured to receive an output of the comparator and to output a signal identifying the power source.

9. The improvement of claim 8, wherein the detection circuit further comprises:
a control circuit configured to receive the output signal and configured to generate a pulse width modulated (PWM) ON/OFF control signal based on the output signal.

10. The improvement of claim 9, wherein the detection circuit further comprises:
a power converter including at least one switching element, wherein the control circuit is electrically coupled to a gate of the switching element, the switching element configured to deliver current to the at least one LED in response to the PWM ON/OFF control signal.

11. In a fluorescent replacement lamp, the improvement of a detection circuit comprising:
a pair of input terminals adapted to receive a voltage source input;
a rectifier connected to the pair of input terminals;
a Zener diode and resistor connected to the filter, such that if the voltage source is an AC line, the Zener diode does not conduct, and if the voltage source is a ballast, a rectified voltage will rise until the Zener diode conducts; and
means for generating a ballast detected signal based on the conduction of the Zener diode.

12. The fluorescent replacement lamp of claim 11, further comprising:
a control circuit configured to operate as a normal line-powered switcher when the Zener diode does not conduct, and the control circuit configured to operate in a ballast mode when a current conducted through the Zener diode is sufficiently high, and voltage across the resistor is above a reference voltage.

13. The improvement of claim 11, wherein the means for generating a ballast detect signal include:
a D flip-flop connected between the Zener diode and the control circuit to be set when current conducted through the Zener diode is sufficiently high, and voltage across the resistor is above a reference voltage, causing the control circuit to operate in a ballast mode in which increasing current drawn from the voltage source decreases power drawn from the voltage source, and vice versa.

14. In a process for supplying a power source for a fluorescent replacement lamp, the improvement comprising:
connecting a detection circuit between the power source and the fluorescent replacement lamp, the detection circuit for identifying a type of power source between an AC line and a ballast, and for limiting a maximum voltage applied to the fluorescent replacement lamp.

15. The improvement of claim 14 further comprising:
detecting a high-voltage condition on a rectified input voltage from the power source with the detection circuit.

16. The improvement of claim 14 further comprising:
preventing excessive voltages input from the power source from damaging other components.

17. The improvement of claim 14 further comprising:
preventing conduction through a Zener diode having a Zener voltage setting sufficiently high, when voltage from the AC line is connected to the input;
allowing conduction through the Zener diode having the Zener voltage setting sufficiently low, when voltage from the ballast is connected to the input, wherein the Zener voltage setting is sufficiently low so that any voltage-sensitive components are not damaged; and
detecting a current flowing through the Zener diode to identify the type of power source.

18. The improvement of claim 14 further comprising:
latching a signal from the power source; and
detecting a difference in incremental change to determine the type of power source, since a normal operating point of the fluorescent replacement lamp is very similar for both AC line and ballast operation.

19. The improvement of claim 14 further comprising:
engaging a control system based on the power source identification, wherein the control system is selected from a group consisting of a control algorithm and control circuit;
if a ballast is wrongly identified as an AC line, triggering the control system to be switched to a ballast mode of operation based on rising voltage and Zener diode conduction.

20. The improvement of claim 14 further comprising:
if a Zener diode energy and power capacity is sufficiently high, delaying a start of a control system without damaging other components thereby providing a protective action.
